(19) United States
(12) Patent Application Publication
(10) Pub. No.: US 2025/0042295 A1
(43) Pub. Date: Feb. 6, 2025

(54) BATTERY DATA TRANSMISSION DEVICE, BATTERY MANAGEMENT DEVICE, BATTERY DATA TRANSMISSION METHOD, AND BATTERY DATA TRANSMISSION SYSTEM

(71) Applicant: HITACHI ASTEMO, LTD., Hitachinaka-shi, Ibaraki (JP)

(72) Inventors: Masahiro KAGEYAMA, Tokyo (JP); Yoshimi NOGUCHI, Tokyo (JP); Mutsumi KIKUCHI, Hitachinaka-shi, Ibaraki (JP); Takanori YAMAZOE, Tokyo (JP)

(73) Assignee: HITACHI ASTEMO, LTD., Hitachinaka-shi, Ibaraki (JP)

(21) Appl. No.: 18/716,244

(22) PCT Filed: Jul. 14, 2022
(86) PCT No.: PCT/JP2022/027769

§ 371 Date: Jun. 4, 2024

(30) Foreign Application Priority Data
Dec. 15, 2021 (JP) 2021-203478

(51) Int. Cl. B60L 58/18; B60L 50/60; B60L 58/12

(52) U.S. Cl. CPC B60L 58/18; B60L 50/66; B60L 58/12

(57) ABSTRACT

A battery data transmission device detects the states of a plurality of battery cells, and transmits, via a transmission path, battery data that is data regarding the detected plurality of battery cells. The device includes an encoding unit that has a plurality of encoding modes and encodes the battery data into encoded data, a mode selection unit that selects any one encoding mode from the plurality of encoding modes, and a transmission control unit that transmits, to a battery management device, the encoded data in the encoding mode selected by the mode selection unit, and receives, from the battery management device, reception information on the transmitted data. The mode selection unit selects, when the previous transmission data communication is abnormal according to the reception information from the battery management device, as the encoding mode for the transmission for this time, the encoding mode in which the past battery data is not used in decoding.

### TECHNICAL FIELD

The present invention relates to a battery data transmission device, a battery management device, a battery data transmission method, and a battery data transmission system.

### BACKGROUND ART

For a battery system used for a hybrid automobile, an electric automobile, and the like, an assembled battery configured by connecting a large number of single battery cells as secondary batteries in series is used. In such an assembled battery, for the capacity calculation and the protection management of each single battery cell, the management of the single battery cell is performed by using a monitor IC that monitors the state of the single battery cell and a control IC that controls the charge and discharge states of the single battery cell. Although wired connection is the mainstream between the monitor IC and the control IC, the application of wireless communication has been studied from various reasons, such as weight reduction and cost reduction by connection cable (communication harness) reduction, the expansion of an in-vehicle space, improvement in the degree of freedom of arrangement, and short circuit risk reduction at collision. On the other hand, the monitoring and control of the battery cell are performed at very short intervals (several tens of ms to hundreds of ms), requiring robust communication, but the inside of a vehicle receives disturbance, such as various metals, a high electric current, a passenger, and wireless communication in the vicinity, thereby deteriorating the communication quality. Patent Literature 1 discloses a battery data compression and extension method by which data is stored by using a pair of the electric current value and the voltage value of a battery in each time, the method in which at the compression of the data, an electric current change amount prediction value for this time is calculated by using a voltage value change amount for the previous time and a voltage value change amount for this time, the difference between the electric current change amount prediction value for this time and an actual electric current value change amount for this time is calculated, and the difference is stored as data, and in which at the extension of the data, the electric current change amount prediction value for this time is calculated by using the voltage value change amount for the previous time and the voltage value change amount for this time, the electric current change amount prediction value for this time is added with the difference between the electric current change amount prediction value for this time and the actual electric current value for this time, and the electric current value change amount for this time is calculated.

### CITATION LIST

### Patent Literature

Patent Literature 1: Japanese Unexamined Patent Application Publication No. 2014-230124

### SUMMARY OF INVENTION

### Technical Problem

In the invention described in Patent Literature 1, there is room for improvement in transmission error solution.

### Solution to Problem

In a first aspect of the present invention, a battery data transmission device detects the states of a plurality of battery cells, and transmits, via a transmission path, battery data that is data regarding the detected plurality of battery cells. The device includes an encoding unit that has a plurality of encoding modes and encodes the battery data into encoded data, a mode selection unit that selects any one encoding mode from the plurality of encoding modes, and a transmission control unit that transmits, to a battery management device, the encoded data in the encoding mode selected by the mode selection unit, and receives, from the battery management device, reception information on the transmitted data. The mode selection unit selects, when the previous transmission data communication is abnormal according to the reception information from the battery management device, as the encoding mode for the transmission for this time, the encoding mode in which the past battery data is not used in decoding.

In a second aspect of the present invention, a battery management device includes a transmission control unit that communicates with a battery data transmission device that wirelessly transmits encoded data obtained by encoding battery data, a decoding unit that decodes the encoded data to obtain the battery data, an abnormality detection unit that detects the abnormality of the encoded data received by the transmission control unit or an abnormality when the encoded data is decoded by the decoding unit, and an instruction unit that outputs, to the battery data transmission device, as an encoding mode for the transmission for the next time, an instruction for selecting the encoding mode in which the past battery data is not used in decoding when the abnormality detection unit detects the abnormality.

In a third aspect of the present invention, a battery data transmission method detects the states of a plurality of battery cells and transmits, via a transmission path, battery data that is data regarding the detected plurality of battery cells. The method includes a data encoding process for encoding the battery data by using any one of a plurality of encoding modes, an encoding mode selection process for selecting any one encoding mode from the plurality of encoding modes, and a data transmission and reception process for transmitting, to a battery management device, encoded data in the encoding mode selected by the encoding mode selection process, and receiving, from the battery management device, reception information on the transmitted data. The encoding mode selection process selects, when the previous transmission data communication is abnormal according to the reception information from the battery management device, as the encoding mode for the transmission for this time, the encoding mode in which the past battery data is not used in decoding.

In a fourth aspect of the present invention, a battery data transmission system includes a battery data transmission device that transmits, via a transmission path, encoded data obtained by encoding battery data that is data regarding a battery, and a battery management device that receives the encoded data. An abnormality detection unit that detects the abnormality of the encoded data is included. The battery data transmission device includes an encoding unit that generates the encoded data by using the battery data, and a transmission control unit that transmits, via the transmission path, the encoded data to the battery management device. The encoding unit has, as operation modes, at least a first mode and a second mode. The first mode is a mode that generates the encoded data by using the past battery data. The second mode is a mode that generates the encoded data without using the past battery data. When detecting an abnormality in the encoded data, the abnormality detection unit causes the encoding unit to apply the second mode in encoding for the next time.

### Advantageous Effects of Invention

According to the present invention, the encoding method is changed between the normal and abnormal states in the data encoding for transmitting the battery information, so that the transmission of the information can be maintained even in a situation where a transmission error occurs.

### BRIEF DESCRIPTION OF DRAWINGS

FIG. 1 is an overall configuration diagram of a battery data transmission system according to an embodiment.

FIG. 2 is a schematic diagram illustrating transmission data.

FIG. 3 is a flowchart illustrating the operation of a battery management device.

FIG. 4 is a flowchart illustrating the operation of a battery data transmission device.

FIG. 5 is a flowchart illustrating the operations of the battery data transmission device and the battery management device.

FIG. 6 is a schematic diagram illustrating battery data.

FIG. 7 is a schematic diagram illustrating a time series operation example of the battery data.

FIG. 8 is a configuration diagram of an encoding unit according to the embodiment.

FIG. 9 is a configuration diagram of a decoding unit according to the embodiment.

FIG. 10 is a configuration diagram of an interframe encoding unit according to the embodiment.

FIG. 11 is a configuration diagram of an interframe decoding unit according to the embodiment.

FIG. 12 is a configuration diagram of an intraframe encoding unit according to the embodiment.

FIG. 13 is a configuration diagram of an intraframe decoding unit according to the embodiment.

FIG. 14 is a configuration diagram of an encoding unit according to a first modification example.

FIG. 15 is a schematic diagram illustrating an operation example of entropy encoding according to the first modification example.

FIG. 16 is a configuration diagram of a decoding unit according to the first modification example.

FIG. 17 is a configuration diagram of an encoding unit according to a second modification example.

FIG. 18 is a configuration diagram of a decoding unit according to the second modification example.

FIG. 19 is a schematic diagram illustrating the operations of a third modification example.

FIG. 20 is a configuration diagram of an interframe encoding unit according to the third modification example.

FIG. 21 is a configuration diagram of an interframe decoding unit according to the third modification example.

FIG. 22 is a configuration diagram of an interframe encoding unit according to a fourth modification example.

FIG. 23 is a configuration diagram of an interframe decoding unit according to the fourth modification example.

FIG. 24 is a configuration diagram of an encoding unit according to a fifth modification example.

FIG. 25 is a configuration diagram of a decoding unit according to the fifth modification example.

FIG. 26 is a flowchart illustrating the operation of the battery data transmission device according to a sixth modification example.

### DESCRIPTION OF EMBODIMENTS

### Embodiment

### (Overview)

There is a method by which in transmitting battery data, the battery data is compressed by encoding on the transmission side and is wirelessly transmitted, and then, the data received by a device on the reception side is extended by decoding. When data is compressed and transmitted in this way, the wireless transmission bandwidth can be effectively utilized, and there is an advantage that even if a data error, that is, an error occurs due to the influence of transmission noise and the like, opportunity to retransmit the same data a plurality of number of times in an in-between time is increased. In addition, as compared with the case where data is not compressed, the transmission data amount per unit time is reduced, so that there is also an advantage that the probability in which a data error occurs can be relatively reduced. On the other hand, it is typically known that when there is an error in received data, there is a case where the data before compression cannot be precisely decoded.

As described later, characteristic time series change appears in the battery data according to the stopping, constant speed running, acceleration, deceleration, and the like, which are the running patterns of an automobile, thereby making the optimal data compression method different. Therefore, in this embodiment, data are previously compressed by a plurality of data compression methods, and the data that can be compressed most efficiently is transmitted. In addition, a method for preventing the influence that cannot precisely perform decoding due to a data error from being propagated to the future will be described together.

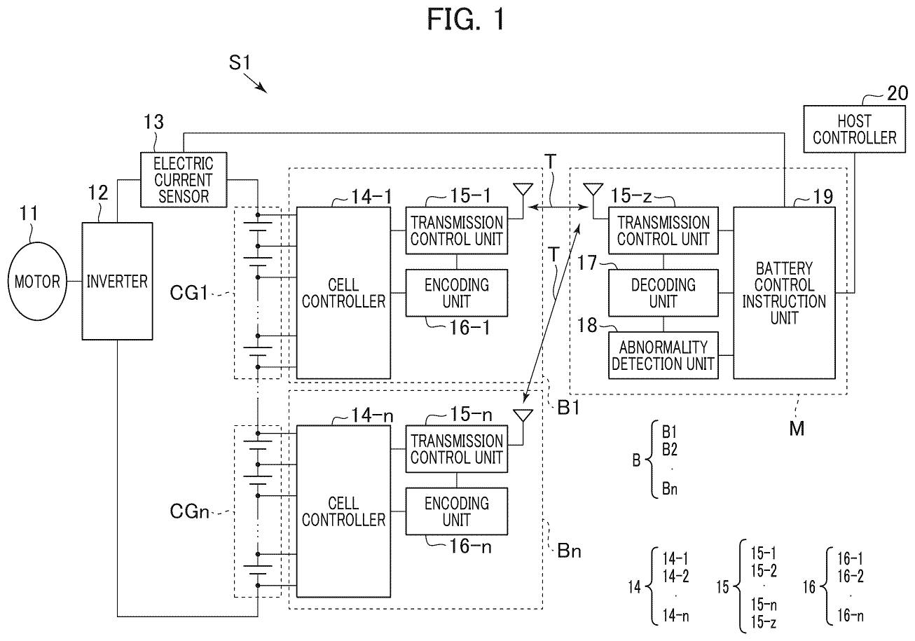

Hereinbelow, the embodiment of a battery data transmission system will be described with reference to FIGS. 1 to 13.

### (Overall Configuration)

FIG. 1 is an overall configuration diagram of a battery data transmission system S1 according to the embodiment. The battery data transmission system S1 includes a motor 11, an inverter 12, an electric current sensor 13, a plurality of cell groups CG, a plurality of battery data transmission devices B, a battery management device M, and a host controller 20. There are a plurality of battery data transmission devices B, each of which is distinguished by indicating a branch number. Note that hereinafter, all the plurality of cell groups CG and each cell included in each cell group CG will also be referred to as a “battery”.

The battery data transmission device B includes a cell controller 14, a transmission control unit 15, and an encoding unit 16. The configurations and operations of the respective battery data transmission devices B are the same. Hereinbelow, there is a case where the specific operation will be described by using a battery data transmission device B1. That is, hereinbelow, there is a case where the specific operation will be described by using a cell controller 14-1, a transmission control unit 15-1, and an encoding unit 16-1, which configure the battery data transmission device B1.

The battery management device M includes a transmission control unit 15-z, a decoding unit 17, an abnormality detection unit 18, and a battery control instruction unit 19. The transmission control unit 15-1 and a transmission control unit 15-n, which are the transmission control units included in the battery data transmission devices B and the transmission control unit 15-z included in the battery management device M are respectively connected by transmission paths T. The transmission path T is a space for wireless communication, and the transmission control unit 15 performs wireless communication.

The inverter 12 supplies electric power stored in the cell group CG into the motor 11, or accumulates, into the cell group CG, electric power obtained from the motor 11. The electric current sensor 13 measures an electric current that flows between the inverter 12 and the cell group CG, and transmits the measurement value to the battery control instruction unit 19.

Each of the cell controller 14, the encoding unit 16, the decoding unit 17, the abnormality detection unit 18, and the battery control instruction unit 19 is, for example, any one of a computer, an FPGA (Field Programmable Gate Array), and an ASIC (Application Specific Integrated Circuit) that is an integrated circuit for specific application. The computer includes a CPU that is a central processing unit, a ROM that is a read-only memory device, and a RAM that is a readable/writable memory device, and performs various calculations in such a manner that the CPU develops a program stored in the ROM into the RAM and executes the program.

The cell controller 14 controls the cell group CG that combines a plurality of cells. The cell controller 14 performs control designated from the battery management device M via the transmission path T. The cell controller 14 includes at least a voltmeter, and measures the voltage of each cell. The cell controller 14 includes other sensors, and for example, may be able to measure each cell temperature. The cell controller 14 may calculate the charge rate (SoC: State Of Charge) of each battery. When receiving a request command described later from the battery management device M, the cell controller 14 transmits information on the connected cell group. The request command includes the designation of an encoding mode, and the cell controller 14 outputs, to the encoding unit 16, information on the designated encoding mode and the information on the cell group CG.

The transmission control unit 15-1 and the transmission control unit 15-n included in the battery data transmission devices B transmit, to the battery management device M, information encoded by the encoding unit 16. In addition, the transmission control unit 15-1 and the transmission control unit 15-n output, to the cell controller 14, the information received from the battery management device M. The transmission control unit 15-z included in the battery management device M outputs, to the decoding unit 17, the information received from the battery data transmission device B. The transmission control unit 15 is a communication module.

The encoding unit 16 encodes, in the designated encoding mode, the information on the cell group CG outputted by the cell controller 14, and outputs the encoded information to the transmission control unit 15. The encoding unit 16 has a plurality of encoding modes, and is operated in the encoding mode designated by the cell controller 14. The decoding unit 17 decodes the information on the cell group CG received from the battery data transmission device B, and outputs the decoded information to the abnormality detection unit 18 and the battery control instruction unit 19. The detail of the encoding unit 16 will be described later.

The abnormality detection unit 18 detects an abnormality caused in the transmission path T. The detail of the abnormality detection will be described later. The battery control instruction unit 19 controls the charge and discharge of the battery, that is, the cell group CG, according to the instruction of the host controller 20. In addition, the battery control instruction unit 19 transmits, to the host controller 20, whether or not the battery is in the normal state. The battery control instruction unit 19 transmits a request command for requesting the transmission of battery data, to each cell controller 14 at a predetermined time, for example, 20 ms elapses each time. The request command includes the information designating the encoding mode. The cell controller 14 obtains the battery data, and encodes the battery data in the designated mode to obtain encoded data. Then, the cell controller 14 transmits the encoded data to the battery management device M. The mode may be the same among all the cell controllers, or may be changed for each cell controller.

### (Abnormality Detection Unit)

The abnormality detection unit 18 detects the abnormality of the transmission path T by using a data error or data nonreception. As the data error, a block code, such as an existing error detection code and a Reed-Solomon code, an error correction code, such as a convolutional code and a concatenated code, the detection of undecodable data, and the like may be used. In addition, the data nonreception detects that data that is periodically transmitted cannot be received within the predetermined time interval. Hereinbelow, each of these will be described.

When detecting an abnormality by using an existing error detection method, for example, a CRC error, the abnormality detection unit 18 calculates the CRC (Cyclic Redundancy Check) of data received from the battery data transmission device B, and judges, when the CRC error has occurred, that an abnormality has occurred in the transmission path T. In addition, when detecting an uncorrectable error that is such as to exceed an existing error correction method, for example, an error correction ability such as the Read-Solomon code, the abnormality detection unit 18 judges that an abnormality has occurred in the transmission path T. In addition, when detecting, in decoding data encoded by using an entropy code such as a Huffman code described later, undecodable data such as an undefined symbol, the abnormality detection unit 18 judges that an abnormality has occurred in the transmission path T.

Note that in the configuration illustrated in FIG. 1, the abnormality detection unit 18 is arranged after the decoding unit 17, but the abnormality detection unit 18 may be arranged before the decoding unit 17. In this case, it is possible to detect, before decoding, that data is undecodable data, for example, such as the case where an uncorrectable error is detected by using the above-described error detection method and error correction method and the case where received data does not satisfy the predetermined code length.

### (Encoding Mode)

The encoding mode includes two modes of a normal mode and an abnormal mode. Hereinbelow, the typical operation of each mode will be described. Cell information transmitted by the cell controller 14 is not limited to voltage information, but here, for simple description, only voltage transmission will be described. Note that hereinbelow, the normal mode will also be referred to as a “first mode”, and the abnormal mode will also be referred to as a “second mode”.

In the encoding unit 16 of the cell controller 14 to which the operation in the normal mode is designated, data in which the latest voltage values of the respective cells are listed may be encoded data, the difference with a past measurement value may be encoded data, and the difference with the cell as a reference within the cell group CG may be encoded data. In addition, in the cell controller 14, instead of using a numerical value as encoded data as-is, encoded data using variable length encoding utilizing a known entropy may be used. The variable length encoding is, for example, Huffman encoding, context adaptive encoding (CAVLC, CABAC, or the like. When encoding based on a previously created table like Huffman encoding and the like is performed, it can also be said that the encoding unit 16 performs a compression process for compressing battery data into encoded data having a data length that is the same as or less than the data length of the battery data. The detail of the operation of the encoding unit 16 in the normal mode will be described later.

The encoding unit 16 of the cell controller 14 to which the operation in the abnormal mode is designated performs encoding in which among the above-described encoding methods in the normal mode, the encoding method in which the difference with a past measurement value is encoded data is excluded. The reason for excluding the encoding method in which the difference with a past measurement value is encoded data and the detail of the operation of the encoding unit 16 in the abnormal mode will be described later.

### (Transmission Data)

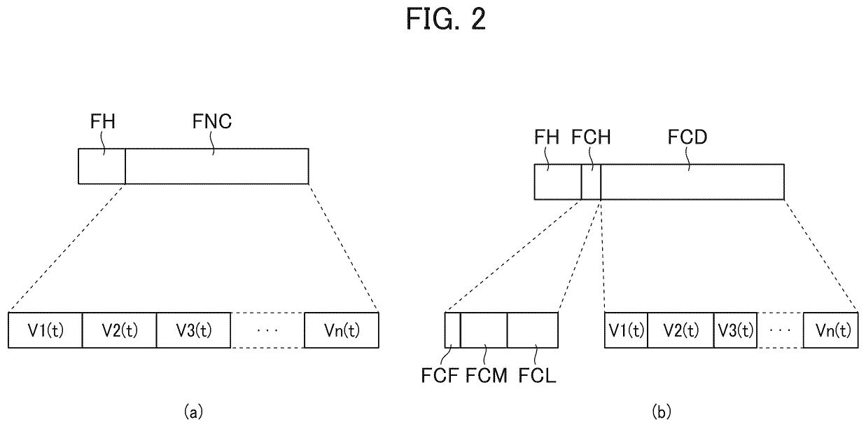

FIG. 2 is a schematic diagram illustrating transmission data transmitted by the transmission control unit 15 of the battery data transmission device B in the normal mode and the abnormal mode. In both modes, a communication header FH is included in the head of the transmission data. The communication header FH is information representing the destination of the transmission data, and is, for example, an IP address and a CAN-ID. There is a case where following the communication header FH, non-compressed data FNC is stored and an encoding header FCH and compressed data FCD are included.

In the non-compressed data FNC, battery data are aligned without being compressed, and for example, digital data (V1(t), V2(t), V3(t), . . . , Vn(t)) of the respective voltage values of n (where n is a positive integer) cells belonging to the cell group CG are described as integer values in millivolt unit, in sequence, from a cell #1 toward a cell #n. Note that the “t” in the parentheses is a symbol representing the time series order of the battery data, and its detail will be described later.

The encoding header FCH is information required for decoding the compressed data FCD, and includes a flag FCF for distinguishing the encoding header FCH and the non-compressed data FNC, mode information FCM representing a compressing method, a code length FCL, and the like. For example, when the flag FCF is 1 bit information having the value of “1”, and in the non-compressed data FNC, the value of “0” is always made to be a head bit, the encoding header FCH and the non-compressed data FNC can be distinguished. The mode information FCM is information for identifying which of the encoding methods described later is used for encoding.

The code length FCL is information representing the length of the compressed data FCD, that is, the number of bits, the number of bytes, and the like, and may include the length of the encoding header FCH. Note that instead of the code length FCL, a code representing the end of the data may be added to the end of the compressed data FCD described next. In addition, when in decoding the compressed data FCD, for example, by comparing the predetermined number (n) of cells belonging to the cell group CG and the number of data (V1(t), V2(t), V3(t), . . . , Vn(t)) obtained in the decoding process, it is possible to identify that the data is the end of the compressed data FCD, the code length FCL may be omitted.

The compressed data FCD is obtained by encoding battery data, and may be fixed length data or variable length data. The detail of the compressed data FCD will be described later. However, the length of the data referred herein is the size of data in the application layer of the OSI reference model, and is not the size of each packet in the second layer and the third layer in the OSI reference model.

### (Flowchart)

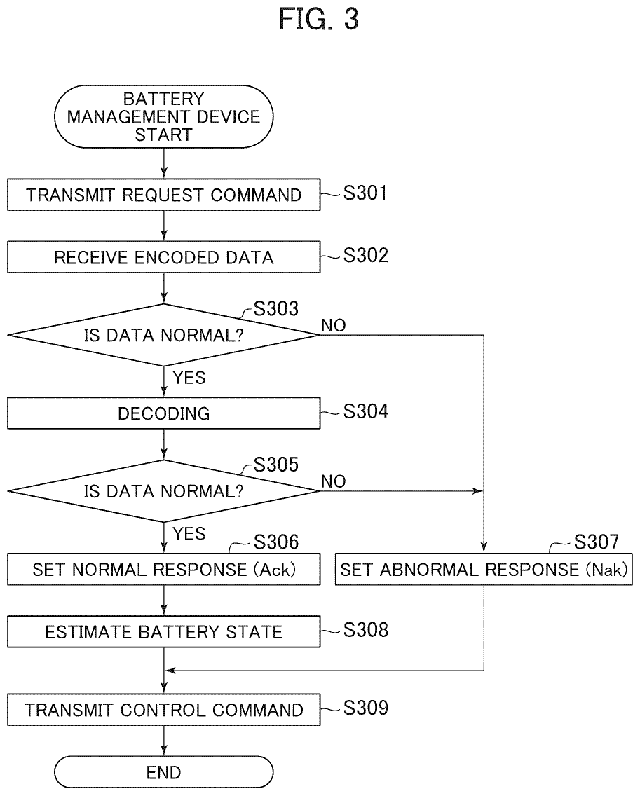

FIG. 3 is a flowchart illustrating the operation of the battery management device M. The battery management device M executes the process illustrated in FIG. 3 at the predetermined time, for example, 20 ms elapses each time. Note that in FIG. 3, the transmission and reception of data between the battery management device M and one battery data transmission device B will be described. The battery management device M executes the process illustrated in FIG. 3 by the number of battery data transmission devices B included in the battery data transmission system S1.

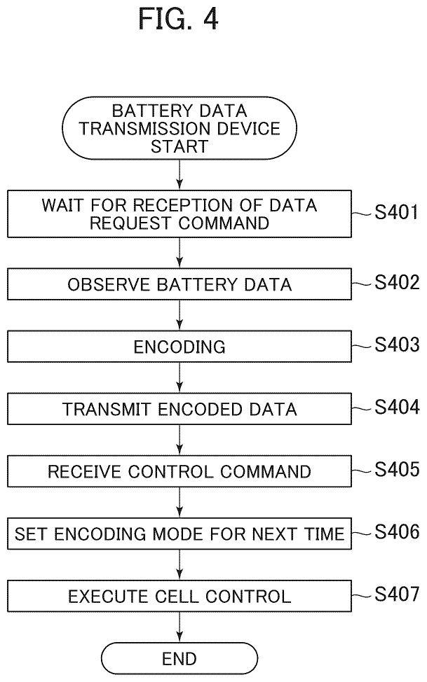

In the step S301, the battery control instruction unit 19 generates a request command with respect to the particular battery data transmission device B, and transmits the request command by using the transmission control unit 15. The battery data transmission device B that has received the request command transmits battery data to the battery control instruction unit 19 according to the flowchart of FIG. 4 described later. In the following step S302, the battery control instruction unit 19 receives encoded data from the battery data transmission device B.

In the following step S303, the battery control instruction unit 19 judges, in the above-described abnormality detection unit 18, whether or not the received encoded data is normal, proceeds to the step S304 when the encoded data is normal, and decodes the encoded data by using the decoding unit 17. On the other hand, in the step S303, when judging that the encoded data is abnormal, the battery control instruction unit 19 proceeds to the step S307. In the step S303, for example, when an uncorrectable data error is detected by using the above-described error detection method and error correction method, when the code length FCL illustrated in FIG. 2(b) does not match the code length of the actually received encoded data, or the like, the battery control instruction unit 19 judges that the encoded data is abnormal. Note that the detail of the decoding method of the step S304 will be described later.

In the step S305, the battery control instruction unit 19 judges, in the above-described abnormality detection unit 18, whether or not the decoded data is normal, and proceeds to the step S306 when the decoded data is normal. On the other hand, when judging that the data decoded in the step S305 is abnormal, the battery control instruction unit 19 proceeds to the step S307. In the step S305, for example, when detecting, in decoding, in the step S304, the data encoded by using the entropy code, the undecodable data such as an undefined symbol, the battery control instruction unit 19 judges that the data is abnormal.

In the step S306, the battery control instruction unit 19 sets a so-called Ack, which is a normal response that is a response representing that the data is normal, as a control command transmitted in the step S309 described later or as a portion of the control command. In the step S307, the battery control instruction unit 19 sets a so-called Nak, which is an abnormal response that is a response representing that the data is abnormal, as a control command transmitted in the step S309 described later or as a portion of the control command. In the step S308, the battery control instruction unit 19 estimates the battery state.

In the step S309 following the step S308 and the step S307, the battery control instruction unit 19 transmits, to the battery data transmission device B, the control command including the normal response or the abnormal response, and ends the process illustrated in FIG. 3. Note that the control command may include forced discharge control (balancing) for preventing the overcharge of the battery, battery forced shutdown control when the abnormal voltage and the abnormal temperature of the battery are detected, and the like.

As described above, when in the step S309, the abnormality detection unit 18 detects the abnormality of the transmission path T immediately before the step S309, the battery control instruction unit 19 transmits, to the battery data transmission device B, the abnormality response (Nak) including an instruction in which the encoding mode for the next time is the abnormal mode. The instruction in which the encoding mode for the next time is the abnormal mode can also be said to be an instruction for setting the encoding method for the next time to the mode in which past data is not used for decoding. Therefore, the battery control instruction unit 19 can also be said to have a role as an “instruction unit” that outputs the instruction for setting the encoding method for the next time to the mode in which past data is not used for decoding.

Note that although not described in FIG. 3, when no sensor data can be obtained from the battery data transmission device B, the battery control instruction unit 19 may notify, to the host controller 20, that an abnormality has occurred in the battery of the battery data transmission system S1.

FIG. 4 is a flowchart illustrating the operation of the battery data transmission device B. When started, the battery data transmission device B performs the operation illustrated in FIG. 4, and when the operation illustrated in FIG. 4 is completed, the battery data transmission device B performs the operation illustrated in FIG. 4 again. That is, the battery data transmission device B repeatedly executes the operation illustrated in FIG. 4.

In the step S401, the battery data transmission device B waits for the reception of the request command from the battery data transmission device B, and when receiving the request command, the battery data transmission device B proceeds to the step S402. Note that the request command received in this step is transmitted in the step S301 of FIG. 3. In the following step S402, the cell controller 14 observes the battery data, that is, obtains the battery information.

In the following step S403, the cell controller 14 designates the encoding mode to the encoding unit 16, and causes the encoding unit 16 to encode the battery data. The encoding mode designated by the cell controller 14 in this step is the normal mode in the initial state, for example, immediately after the turning on the power supply and immediately after the reset of the system, and thereafter, is any one of the normal mode and the abnormal mode designated in the step S406 according to the control command received in the step S405 described later.

In the following step S404, the transmission control unit 15 transmits, to the battery management device M, the encoded data that is the battery data encoded by the encoding unit 16. Note that the encoded data is received in the step S302 of FIG. 3.

In the following step S405, the transmission control unit 15 receives the control command transmitted from the battery management device M. The control command received in this step is transmitted in the step S309 of FIG. 3. As described above, the control command includes the normal response when the data can be normally decoded in the battery management device M, and the abnormal response when the data cannot be normally decoded in the battery management device M. In addition, when the control command cannot be received within the predetermined time due to the abnormality of the transmission path T or the like, the transmission control unit 15 judges that there is no response, and proceeds to the step S406.

In the following step S406, when the control command received in the step S405 includes the normal response (Ack) the transmission control unit 15 sets, to the normal mode, the encoding mode of the encoding unit 16 in executing the step S403 for the next time. On the other hand, when the control command received in the step S405 includes the abnormal response (Nak), or when there is no response, the transmission control unit 15 sets, to the abnormal mode, the encoding mode of the encoding unit 16 in executing the step S403 for the next time.

In the following step S407, the cell controller 14 executes cell control according to the control command received in the step S405, and ends the process illustrated in FIG. 4. The cell control may include forced discharge control for preventing the overcharge of the battery, the battery forced shutdown control when the abnormal voltage and the abnormal temperature of the battery are detected, and the like. Note that without including the battery forced shutdown control in the cell control, the cell control may perform control so as to transmit the request of the battery shutdown to the battery management device M.

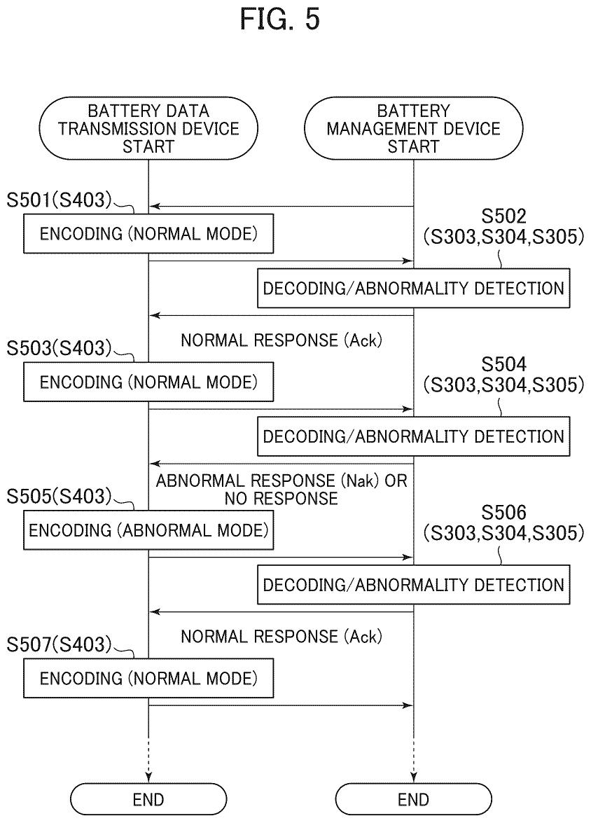

FIG. 5 is a flowchart illustrated in time series by extracting, from the flowcharts of FIGS. 3 and 4, the main steps regarding the cooperation of the encoding operation of the battery data transmission device B and the decoding and abnormality detection operation of the battery management device M. The main steps are the step S403 illustrated in FIG. 4 for the battery data transmission device B, and the steps S303, S304, and S305 illustrated in FIG. 3 for the battery management device M.

First, the battery management device M causes the battery data transmission device B to be started. In the first step S501, the battery data transmission device B performs encoding in the normal mode since the battery data transmission device B is in the state immediately after being started, and transmits the encoded data to the battery management device M. In the step S502, the battery management device M performs decoding and abnormality detection, and here, returns the normal response to the battery data transmission device B. The battery data transmission device B that has received the normal response performs encoding in the normal mode again in the step S503, and transmits the encoded data.

In the following step S504, the battery management device M performs decoding and abnormality detection, and here, returns the abnormal response to the battery management device M or performs no response. Upon this, the battery data transmission device B performs encoding in the abnormal mode in the step S505, and transmits the encoded data to the battery management device M. In the step S506, the battery management device M performs decoding and abnormality detection, and here, returns the normal response to the battery data transmission device B. The battery data transmission device B that has received the normal response performs encoding in the normal mode again in the step S507, and transmits the encoded data. Hereinbelow, likewise, the transmission and reception between the battery data transmission device B and the battery management device M are continued.

### (Battery Data)

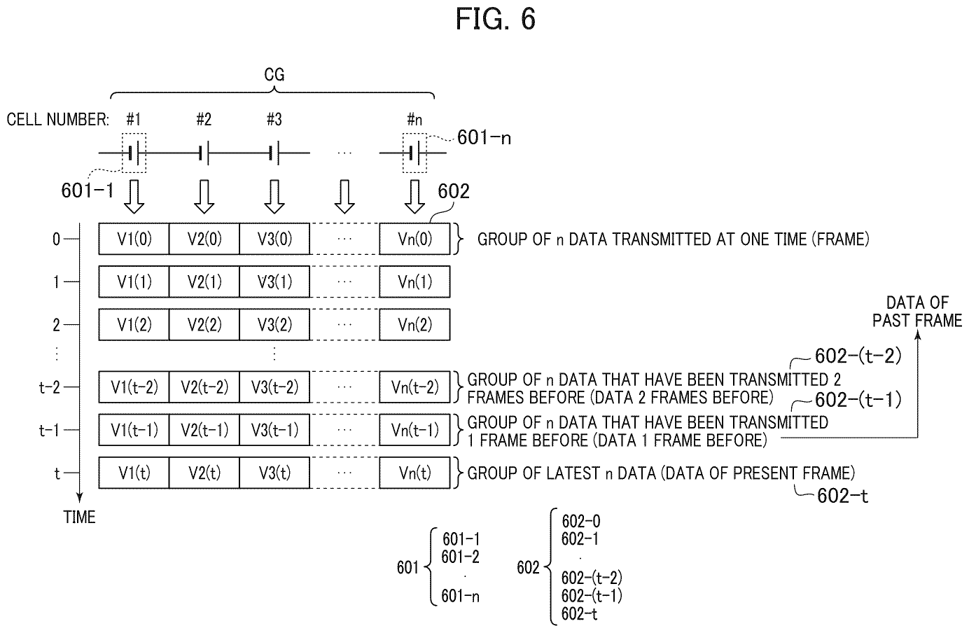

FIG. 6 is a schematic diagram illustrating battery data. The cell group CG is configured of n cells, which will be referred to as cell numbers #1, #2, #3, . . . , #n from the left side in the illustration. These n battery data will be referred to as V1, V2, V3, . . . , Vn. Hereinafter, a group of n data transmitted at one time will be referred to as a “frame”. In addition, the numerical value in the parentheses indicated after the name of each battery data represents the time series order of the battery data. For example, the “V1(1)” represents the first battery data of the cell number #1, and the “V3(t−2)” represents the (t−2)th battery data of the cell number #3.

In the following description, the latest time series number is the “t”, and the V1(t) to the Vn(t) will be referred to as “the data of the present frame” or “the data of the latest frame”. The V1(t−1) to the Vn(t−1) represent a group of n data that have been transmitted 1 frame before with reference to the present, and hereinafter, will be referred to as “data 1 frame before”. In addition, the V1(t−2) to the Vn(t−2) represent a group of n data that have been transmitted 2 frames before, and hereinafter, will be referred to as “data 2 frames before”. In addition, hereinafter, the data of the frames before the present including the data 1 frame before will be collectively referred to as “the data of the past frame” or “past data”.

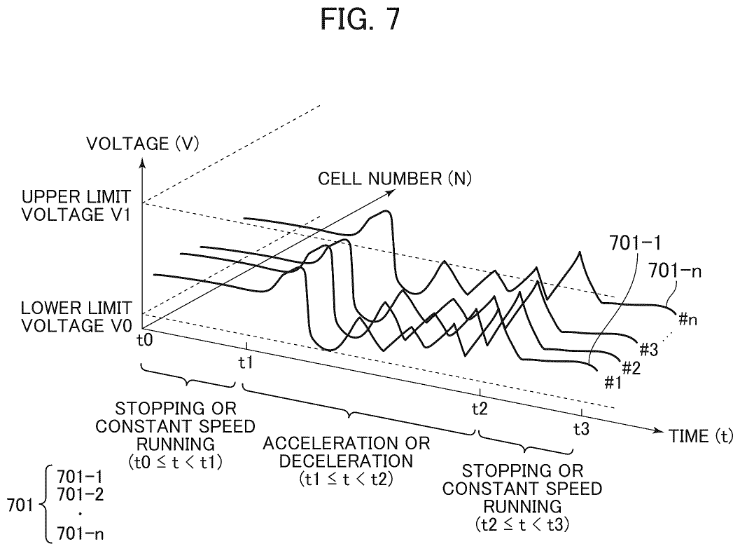

FIG. 7 is a schematic diagram illustrating the time series change of the battery data. FIG. 7 is a three-dimensional graph in which three axes of the voltage axis, the cell number axis, and the time axis are orthogonal. In the voltage axis, the voltage is higher toward the upper side of the illustration. The cell number axis represents that the cell number #1 is on the front side of the illustration, and the cell number #n is on the rearmost side of the illustration. The time axis represents that time elapses from the left to the right in the illustration. The t0 to the t3 indicated on the time axis are time provided conveniently for the description, and do not represent the correlation with the “t” that is the present time series number illustrated in FIG. 6.

In view of the entire FIG. 7, it is found that although there is change in the left-right direction in the illustration, that is, in time series, the difference between the voltages of the cells in the rear direction in the illustration, that is, at the same time is small. Hereinbelow, this will be studied in detail. In the example illustrated in FIG. 7, at the time t0 to t1, stopping or constant speed running is performed, and the respective cell voltages are substantially constant. At the time t1 to t2, acceleration or deceleration is performed, and the respective cell voltages are largely changed in time series. At the time t2 to t3, stopping or constant speed running is performed again, and the respective cell voltages are substantially constant.

When the cell voltages are substantially constant in time series, the difference between “the data of the past frame” and “the data of the present frame” becomes small and becomes a value close to zero, so that by transmitting the difference, the number of bits when data is represented in binary, that is, the transmission data amount is reduced, thereby enabling data compression. In this way, the encoding method for performing data compression by using the “data of the past frame” will be referred to as “interframe encoding”. Note that “the past frame” can be arbitrarily selected in such a manner that “the past frame” is not only 1 frame before, but also 2 frames before, 3 frames before, and the like.

On the other hand, when the cell voltage is significantly changed in time series, the “difference” between “the data of the past frame” and “the data of the present frame” becomes a large value, that is, a value far from 0. Accordingly, by using the uniform increase and decrease in the voltages in the respective cells with the individual batteries being connected in series as illustrated in FIG. 6, the difference is taken only in “the data of the present frame” to be a small value, that is, a value close to zero, so that the data amount transmitted is compressed. In this way, the encoding method for performing data compression only in “the data of the present frame” will be referred to as “intraframe encoding”.

### (Encoding Unit and Decoding Unit)

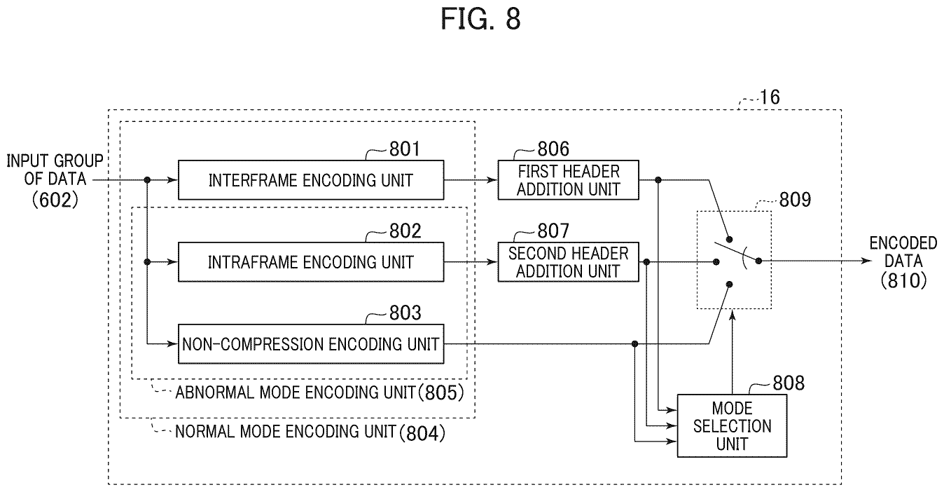

FIG. 8 is a functional configuration diagram of the encoding unit 16 according to the embodiment. The encoding unit 16 includes an interframe encoding unit 801, an intraframe encoding unit 802, a non-compression encoding unit 803, a first header addition unit 806, a second header addition unit 807, a mode selection unit 808, and a switching unit 809. A normal mode encoding unit 805 includes the interframe encoding unit 801, the intraframe encoding unit 802, and the non-compression encoding unit 803. An abnormal mode encoding unit 804 is configured of the intraframe encoding unit 802 and the non-compression encoding unit 803. That is, the abnormal mode encoding unit 804 has a configuration in which the interframe encoding unit 801 is excluded from the normal mode encoding unit 805.

The interframe encoding unit 801 and the intraframe encoding unit 802 output the compressed data FCD illustrated in FIG. 2(b). The non-compression encoding unit 803 outputs the non-compressed data FNC illustrated in FIG. 2(a). The first header addition unit 806 and the second header addition unit 807 add the encoding header FCH illustrated in FIG. 2(b).

The mode selection unit 808 judges which one of the encoded data outputted from three encoding units of the interframe encoding unit 801, the intraframe encoding unit 802, and the non-compression encoding unit 803 is to be selected, and instructs the selected encoded data to the switching unit 809. In principle, the mode selection unit 808 adopts, among the encoded data outputted by the three encoding units, the encoded data having the shortest data length, in other words, a small size. However, the mode selection unit 808 does not select the interframe encoding in the abnormal mode. Note that when a plurality of data having the shortest code are present, the data is selected according to the priority order of the non-compression encoding, the intraframe encoding, and the interframe encoding.

The non-compression encoding by the non-compression encoding unit 803 is, for example, encoding that converts a plurality of battery data represented by 14 bits per battery into a data string having continuous 8 bits (1 byte). This can be achieved by a small calculation amount, but there is no data compression effect. The intraframe encoding by the intraframe encoding unit 802 has an advantage that even when a data error occurs in transmission, the data error is not propagated to the future in decoding, and on the other hand, the data compression effect is not large.

The interframe encoding by the interframe encoding unit 801 has an advantage that the data compression effect is typically large, and on the other hand, has a disadvantage that when a data error has occurred in transmission, the data error is propagated to the future in decoding. Therefore, when data has the same code length outputted by other encoding, the mode other than the interframe encoding is desirably selected. The switching unit 809 selects and outputs any one of the encoded data according to the selection result of the mode selection unit 808.

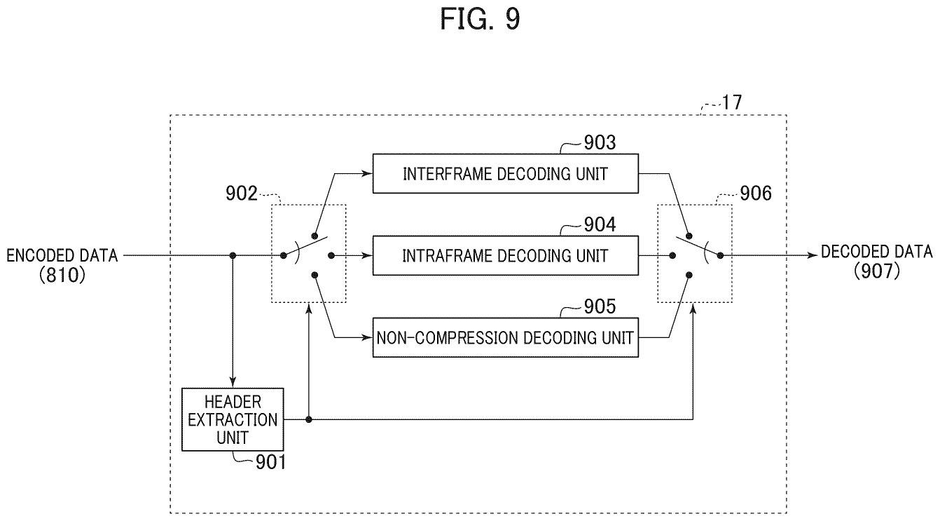

FIG. 9 is a functional configuration diagram of the decoding unit 17 according to the embodiment. The decoding unit 17 decodes encoded data 810 to obtain decoded data 907. The decoding unit 17 includes a header extraction unit 901, a decoding mode selection unit 902, an interframe decoding unit 903, an intraframe decoding unit 904, a non-compression decoding unit 905, and an output selection unit 906.

The header extraction unit 901 extracts the header of the encoded data 810, decides, from the contents of the header, which one of the interframe decoding unit 903, the intraframe decoding unit 904, and the non-compression decoding unit 905 is selected, and instructs the selected decoding unit to the decoding mode selection unit 902 and the output selection unit 906. The decoding mode selection unit 902 outputs the encoded data 810 to the decoding unit instructed from the header extraction unit 901. The details of the operations of the interframe decoding unit 903 and the intraframe decoding unit 904 will be described later. For example, the non-compression decoding unit 905 takes out the battery data represented by 14 bits per battery from a data string having continuous 8 bits (1 byte). The output selection unit 906 outputs, as the decoded data 907, the output of the decoding unit instructed from the header extraction unit 901.

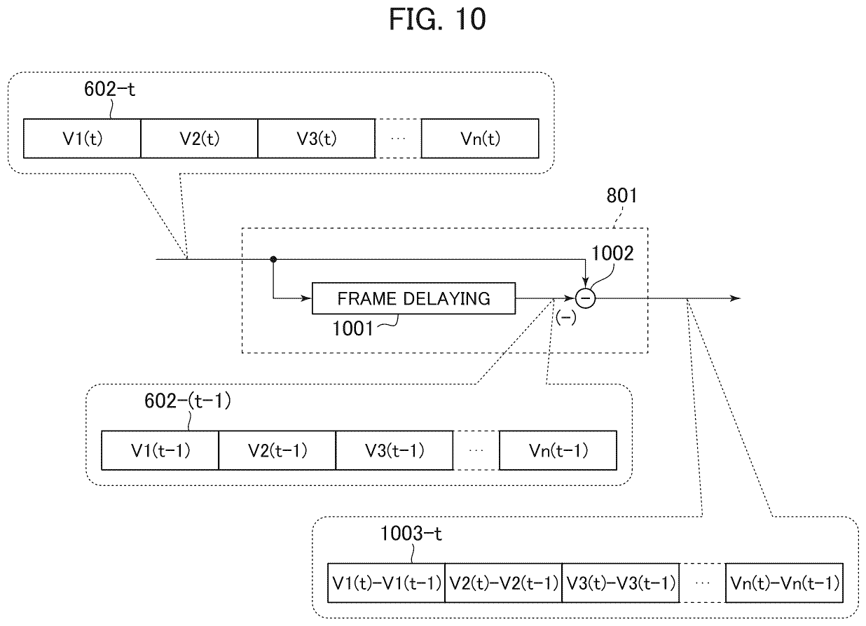

FIG. 10 is a configuration diagram of the interframe encoding unit 801 according to the embodiment. The interframe encoding unit 801 includes a frame delaying unit 1001 and a subtractor 1002. The interframe encoding unit 801 subtracts, for each cell, data 1 frame before (602-(t−1)) from the data of the present frame (602-t), and outputs interframe encoded data (1003-t). To store the data 1 frame before, the frame delaying unit 1001 is provided, and for the subtraction process, the subtractor 1002 is provided.

Note that in FIG. 10, only one frame delaying unit 1001 is used to output the difference with the data 1 frame before (602-(t−1)), but when two frame delaying units 1001 are connected in series, the difference with data 2 frames before (602-(t−2)) may be outputted. In addition, the difference with the data 1 frame before (602-(t−1)) and the difference with the data 2 frames before (602-(t−2)) may be outputted in parallel, and the mode selection unit 808 may select any one of the differences. Further, data 3 or more frames before may be used.

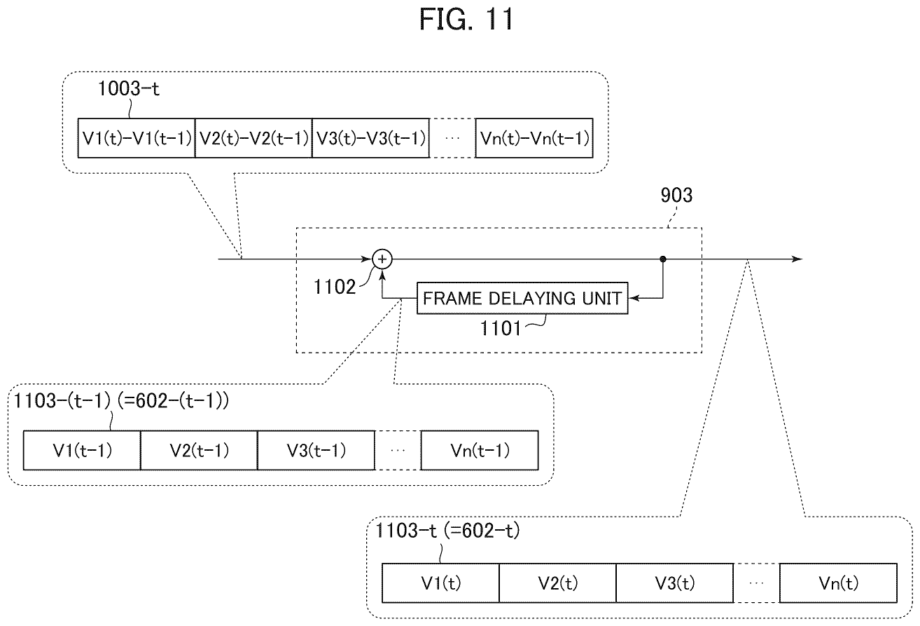

FIG. 11 is a configuration diagram of the interframe decoding unit 903 according to the embodiment. The interframe decoding unit 903 includes a frame delaying unit 1101 and an adder 1102. The adder 1102 adds, for each cell, the data of the present frame (1003-t) and data 1 frame before (1103-(t−1)) outputted by the frame delaying unit 1101, and outputs decoded data (1103-t).

Here, attention is required in that the frame delaying unit 1101 and the adder 1102 have a feedback configuration. If an uncorrectable data error remains in the decoded data (1103-t), the error is sequentially propagated into the future (t+1, t+2, . . . ), and the influence of the data error is increased. Therefore, as illustrated in the flowchart of FIG. 5, when an abnormality is detected by the battery management device M, switching to the “abnormal mode” is performed in encoding for the next time in the battery data transmission device B. With this, the interframe encoding that is encoding using the past battery data in decoding cannot be selected, and the error is prevented from being propagated to the future (t+1, t+2, . . . ).

Note that like the configuration of the interframe encoding unit 801 illustrated in FIG. 10, in the case of using one frame delaying unit 1001 and “the one frame difference”, “the abnormal mode” should be only for a period of one frame. However, in the case of using two frame delaying units 1001 and “the two frame difference”, “the abnormal mode” is required to be continued for a period of two frames. Likewise, in the case of using the three frame difference or more, the period of the abnormal mode” is required to be increased to three frames or more.

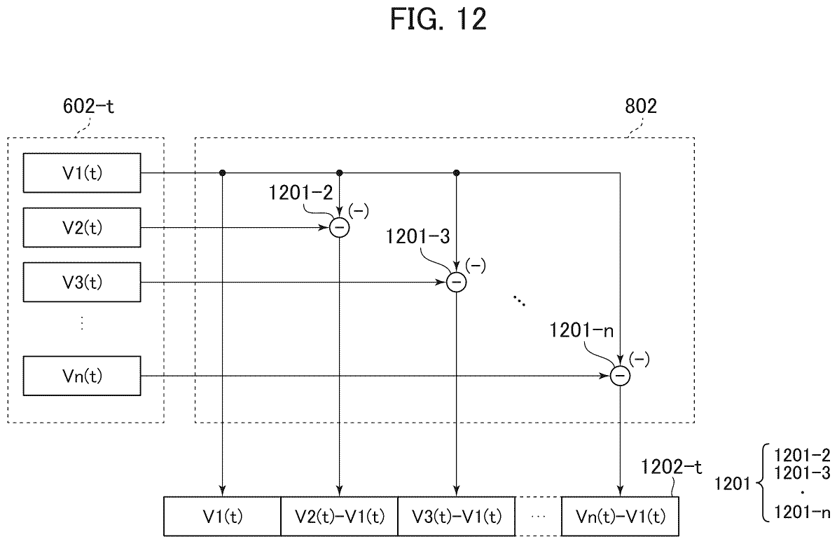

FIG. 12 is a configuration diagram of the intraframe encoding unit 802 according to the embodiment. The intraframe encoding unit 802 includes a plurality of subtractors 1201-2, 1201-3, . . . , 1201-n. These subtractors calculate the differences between the battery data (V1(t)) of the cell #1 as a reference and the respective battery data (V2(t) to Vn(t)) of the cells #2 to #n. Then, the intraframe encoding unit 802 outputs, as intraframe encoded data 1202-t, the battery data (V1(t)) of the cell #1 and these differences. Note that although in FIG. 12, the battery data of the cell #1 is a reference, the battery data of the cells (#2 to #n)) other than the cell #1 may be a reference.

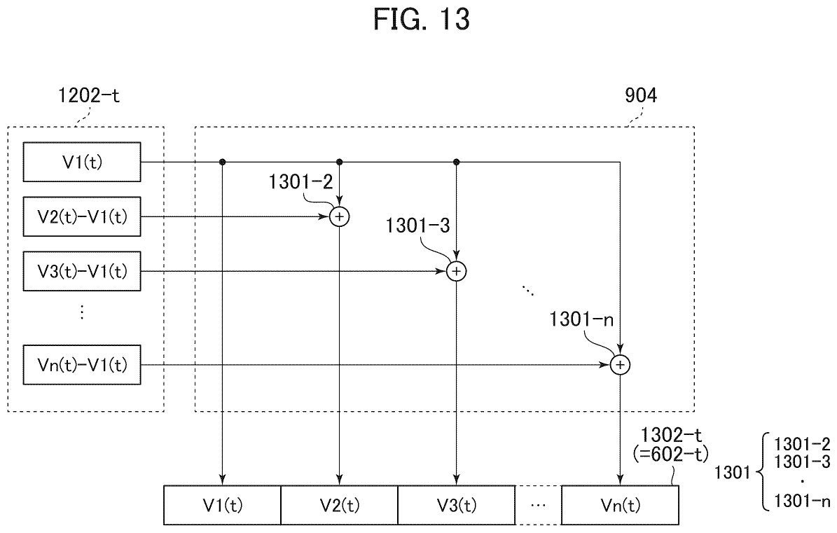

FIG. 13 is a configuration diagram of the intraframe decoding unit 904 according to the embodiment. The intraframe decoding unit 904 includes a plurality of adders 1301-2, 1301-3, . . . , 1301-n. These adders add the battery data (V1(t)) of the cell #1 as a reference to the respective difference data included in the encoded data, and obtains the respective battery data (V2(t) to Vn(t)) of the cells #2 to #n.

According to the above-described embodiment, the following operation and effect are obtained.

(1) The battery data transmission device B detects the states of a plurality of battery cells, and transmits, via the transmission path T, battery data that is data regarding the detected plurality of battery cells, to the battery management device M. The battery data transmission device B includes the encoding unit 16 that has a plurality of encoding modes and encodes the battery data, the mode selection unit 808 that selects any one encoding mode from the plurality of encoding modes, and the transmission control unit 15 that transmits, to the battery management device M, the encoded data in the encoding mode selected by the mode selection unit 808, and receives, from the battery management device M, reception information on the transmitted data. The mode selection unit 808 selects, when the previous transmission data communication is abnormal according to the reception information from the battery management device M, as the encoding mode for the transmission for this time, the encoding mode in which the past battery data is not used in decoding. Therefore, the encoding method is changed between the normal state and the abnormal state, and the transmission of the information can be maintained even in a situation in which a transmission error occurs.
(2) In the battery data transmission device B, the encoding unit 16 includes a first encoding unit that performs encoding by using the past battery data, that is, the interframe encoding unit 801, and a second encoding unit that performs encoding without using the past battery data, that is, the intraframe encoding unit 802 and the non-compression encoding unit 803.
(3) The mode selection unit 808 selects the encoding mode that has generated, among a plurality of encoded data calculated by the encoding unit 16, the encoded data having the shortest code length. Therefore, among the plurality of encoding modes, the encoding mode that outputs the minimum data can be reliably selected. Although the selection of the optimal encoding mode according to the running mode of the vehicle is not impossible, the relationship between the running mode and the optimal encoding mode is not absolute, and a slight time is required for the judgement of the running mode. Therefore, although the calculation amount is slightly increased, the encoded data is previously calculated by the plurality of methods like this embodiment, which is a reliable method for obtaining the minimum data.
(4) The battery management device M includes the transmission control unit 15-z that communicates with the battery data transmission device that wirelessly transmits encoded data obtained by encoding battery data, the decoding unit 17 that decodes the encoded data to obtain the battery data, the abnormality detection unit 18 that detects the abnormality of the encoded data received by the transmission control unit or an abnormality when the encoded data is decoded by the decoding unit, and the instruction unit that outputs, to the battery data transmission device, as an encoding mode for the transmission for the next time, an instruction for selecting the encoding mode in which the past battery data is not used in decoding when the abnormality detection unit 18 detects the abnormality (the steps S305 to S309 of FIG. 3, the battery control instruction unit 19). Therefore, the battery management device M notifies the abnormality of the received data to the battery data transmission device B, thereby enabling to prevent the error from being propagated to the future at the occurrence of the abnormality.
(5) The battery data transmission system S1 includes the battery data transmission device B that transmits, via the transmission path, encoded data obtained by encoding battery data that is data regarding a battery, and the battery management device M that receives the encoded data. The abnormality detection unit 18 that detects the abnormality of the encoded data is included. The battery data transmission device B includes the encoding unit 16 that generates the encoded data by using the battery data, and the transmission control units 15-1 to 15-n that transmit, via the transmission path, the encoded data to the battery management device. The encoding unit 16 has, as operation modes, at least the first mode and the second mode. The first mode is a mode that generates the encoded data by using the past battery data. The second mode is a mode that generates the encoded data without using the past battery data. When detecting an abnormality in the encoded data, the abnormality detection unit 18 causes the encoding unit to apply the second mode in encoding for the next time. Therefore, the battery data transmission system S1 changes the encoding method between the normal state and the abnormal state, and can maintain the transmission of the information even in a situation where a transmission error occurs.

### First Modification Example

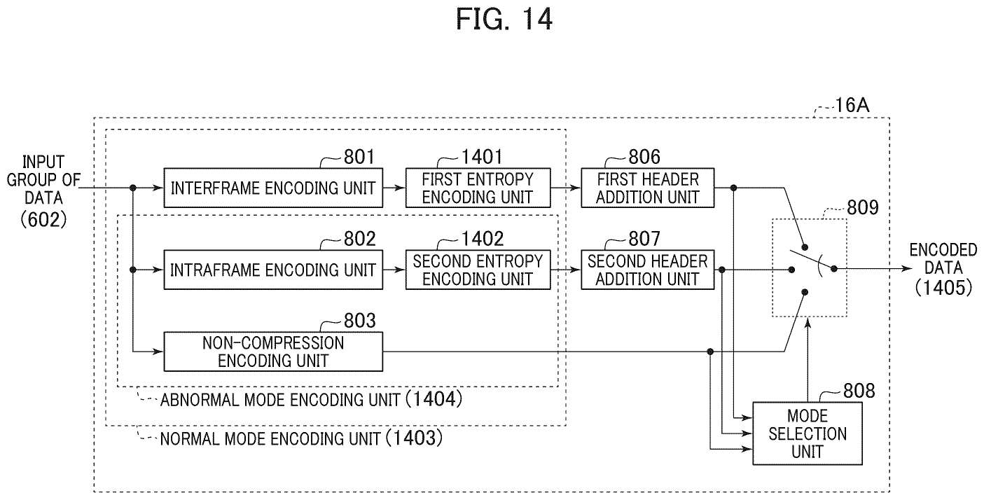

FIG. 14 is a configuration diagram of an encoding unit 16A according to a first modification example. In the encoding unit 16A, the configuration of the encoding unit 16 according to the embodiment is added with a first entropy encoding unit 1401 and a second entropy encoding unit 1402. In this modification example, like the following description, data is converted into a variable length code to be able to be compressed to have a smaller data amount.

Entropy encoding is a reversible encoding technique by which the original data is converted into another code on the basis of the data appearance frequency, thereby compressing the data having the same information into a smaller data amount. The first entropy encoding unit 1401 and the second entropy encoding unit 1402 perform this entropy encoding. The first entropy encoding unit 1401 performs the entropy encoding with respect to the output of the interframe encoding unit 801, and outputs the entropy encoded data to the first header addition unit 806. The second entropy encoding unit 1402 performs the entropy encoding with respect to the output of the intraframe encoding unit 802, and outputs the entropy encoded data to the second header addition unit 807. The first entropy encoding unit 1401 and the second entropy encoding unit 1402 have different input sources and output destinations, but have the same operation.

Most of the differences between the frames of the battery data and the differences between the cells in the same frames become a value close to “0”. Therefore, in the entropy encoding, a relatively short code is assigned to the data having a small absolute value. On the other hand, the case where the difference becomes a large value, for example, the case where the voltage value is different as much as several hundreds of millivolts from the previously measured voltage value, is rare, so that in the entropy encoding, a long code is assigned to the data having a large absolute value. In this way, the variable length code is assigned according to the appearance frequency of each data value, so that the entire transmission data can be compressed into a smaller data amount. Representative examples of the entropy encoding include a Huffman code, a Shannon code, an arithmetic code, a range code, and the like, and in this embodiment, any of these may be adopted. Hereinbelow, an example of the case of using the Huffman code will be described.

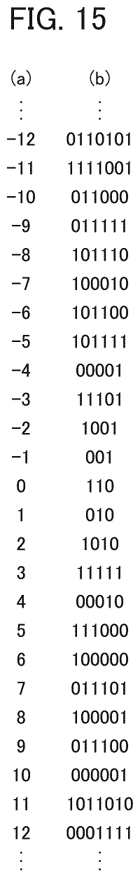

FIG. 15 is a diagram illustrating an example of a Huffman table. In the Huffman code, a conversion table referred to as the Huffman table is previously prepared, and encoding and decoding can be achieved simply by pulling this conversion table, so that the calculation amount is relatively small, thereby enabling high speed operation. Encoding is performed by converting the input data in decimal illustrated in FIG. 15(a) into the output data in binary illustrated in FIG. 15(b) one on one. On the contrary, decoding is performed by converting the input data in binary illustrated in FIG. 15(b) into the output data in decimal illustrated in FIG. 15(a) one on one.

For example, the three continuous input data in decimal “−1, 0, 1” is encoded into the “001110010” of the continuous output data in binary (symbol), and on the contrary, the “001110010” of the continuous input data in binary (symbol) is decoded into the three continuous output data in decimal “−1, 0, 1”. By using a large number of sample data, the Huffman table is previously set on the basis of the appearance frequency of the data. Therefore, when the sample data used for the setting is changed, the contents of the Huffman table are also changed.

The output of the interframe encoding unit 801, that is, the frame difference and the output of the intraframe encoding unit 802, that is, the difference between the cells in the same frame have different data value appearance frequency. Therefore, it is desirable that the first entropy encoding unit 1401 and the second entropy encoding unit 1402 previously create respective different Huffman tables, and hold the Huffman tables.

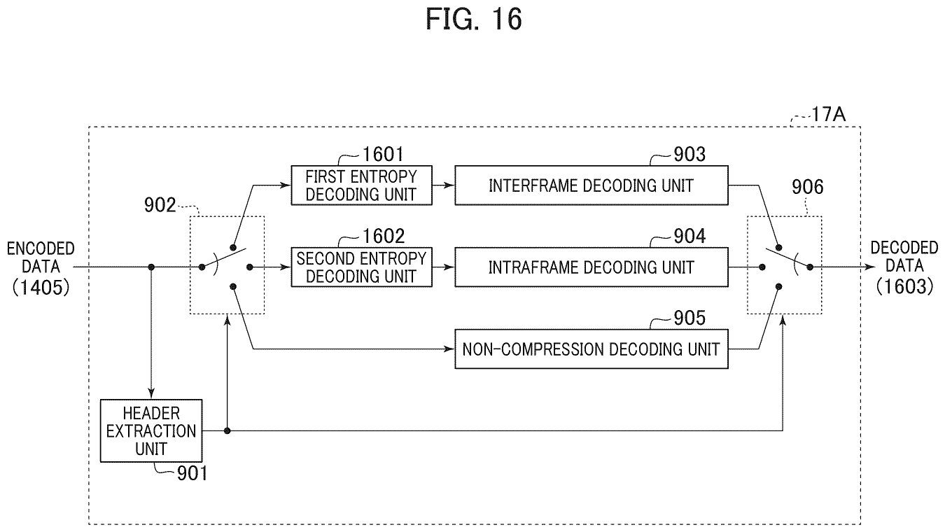

FIG. 16 is a configuration diagram of a decoding unit 17A according to the first modification example. In FIG. 16, the configuration of the decoding unit 17 illustrated in FIG. 9 is added with a first entropy decoding unit 1601 and a second entropy decoding unit 1602. The first entropy decoding unit 1601 and the second entropy decoding unit 1602 perform entropy decoding by using, for example, the Huffman tables illustrated in FIG. 15, and decode encoded data (1405) outputted by the encoding unit 16 of FIG. 14.

According to the first modification example, the entropy encoding is adopted for the encoding, and the data length of the encoded data can be reduced regardless of the presence or absence of an abnormality in communication. Note that the Huffman table may be updated as appropriate. For example, the data may be accumulated when the vehicle is driven, and the Huffman table may be updated when the vehicle is stopped.

### Second Modification Example

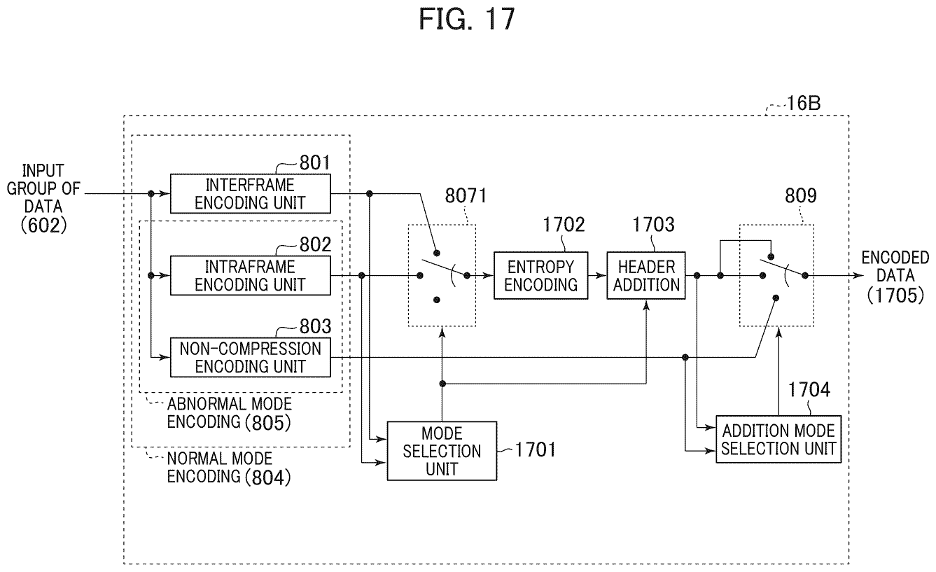

FIG. 17 is a configuration diagram of an encoding unit 16B according to a second modification example. The encoding unit 16B according to this modification example has a configuration in which the two entropy encoding units that the encoding unit 16A illustrated in FIG. 14 in the first modification example has are combined and moved. A mode selection unit 1701 compares the total of the absolute values of the respective outputs of the interframe encoding unit 801 and the intraframe encoding unit 802, thereby causing a selection unit 8071 to select the output having the smaller total value. However, the mode selection unit 1701 may use the average value of the absolute values instead of the total of the absolute values. That is, the mode selection unit 1701 may compare the averages of the absolute values of the respective outputs of the interframe encoding unit 801 and the intraframe encoding unit 802, thereby causing the selection unit 8071 to select the output having the smaller total value.

An addition mode selection unit 1704 compares the code lengths of the output of a header addition unit 1703 and the output of the non-compression encoding unit 803, thereby causing the switching unit 809 to select the code having the shorter code length. Note that the output of the header addition unit 1703 is the sum of the encoding header FCH and the compressed data FCD illustrated in FIG. 2(b). The output of the non-compression encoding unit 803 is the non-compressed data FNC illustrated in FIG. 2(a).

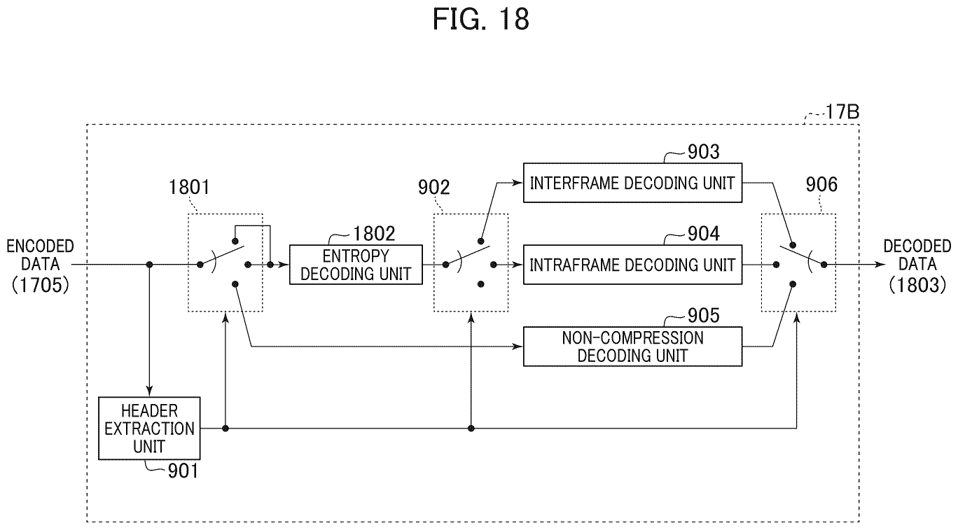

FIG. 18 is a configuration diagram of a decoding unit 17B according to the second modification example. The decoding unit 17B according to this modification example has a configuration in which the two entropy decoding units that the decoding unit 17A illustrated in FIG. 16 in the first modification example has are combined and moved. An entropy decoding unit 1802 decodes encoded data 1705 outputted by the encoding unit 16B.

According to the second modification example, since the calculation amount is reduced, even the powerless CPU such as a microcomputer can be operated at high speed.

### Third Modification Example

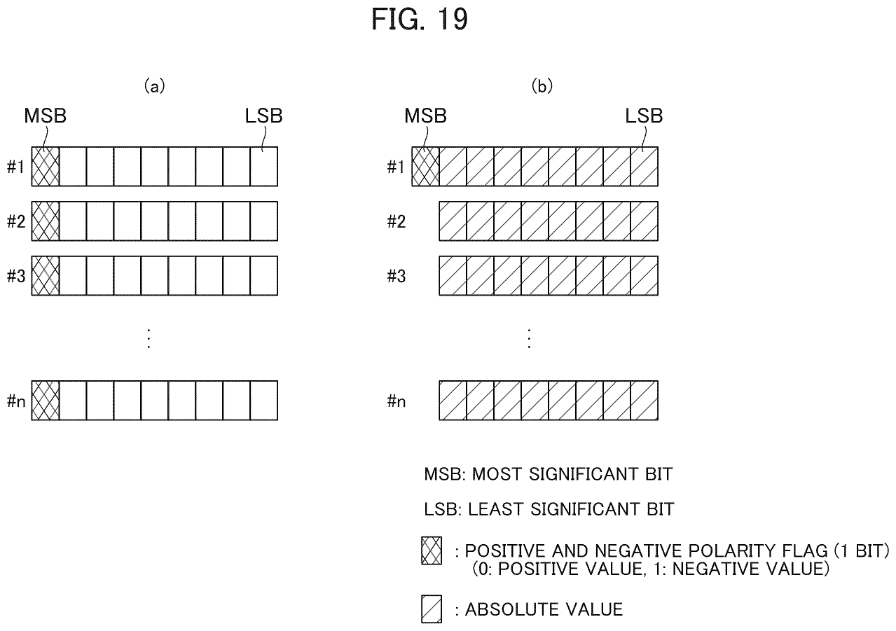

FIG. 19 is a schematic diagram illustrating data recoding methods according to a third modification example. Specifically, FIG. 19(a) illustrates the recoding method according to the embodiment, and FIG. 19(b) illustrates the data recoding method according to this modification example. FIG. 19(a) is a schematic diagram illustrating, with respect to n battery data, n data outputted by the interframe encoding unit 801 for each bit from an MSB (most significant bit) to an LSB (Least Significant Bit). In FIG. 19(a), the MSB is a positive and negative polarity flag. The positive and negative polarity flag denotes a flag representing whether data has a positive value or a negative value. In FIG. 19(b), the same n data are divided into the “positive and negative polarity flags” and “the absolute values”, and further, “the positive and negative polarity flags” are collectively represented by one bit.

As illustrated in FIGS. 1 and 6, since all the battery cells are connected in series, the increase and decrease tendencies in the voltages of the respective battery cells also substantially match. Therefore, since the “positive and negative polarity flags” of the frame difference data basically match in all of the n data, the “positive and negative polarity flags” can be combined into 1 bit like FIG. 19(b), and as a result, the data amount can be reduced by the (n−1) bit as compared with the expression illustrated in FIG. 19(a).

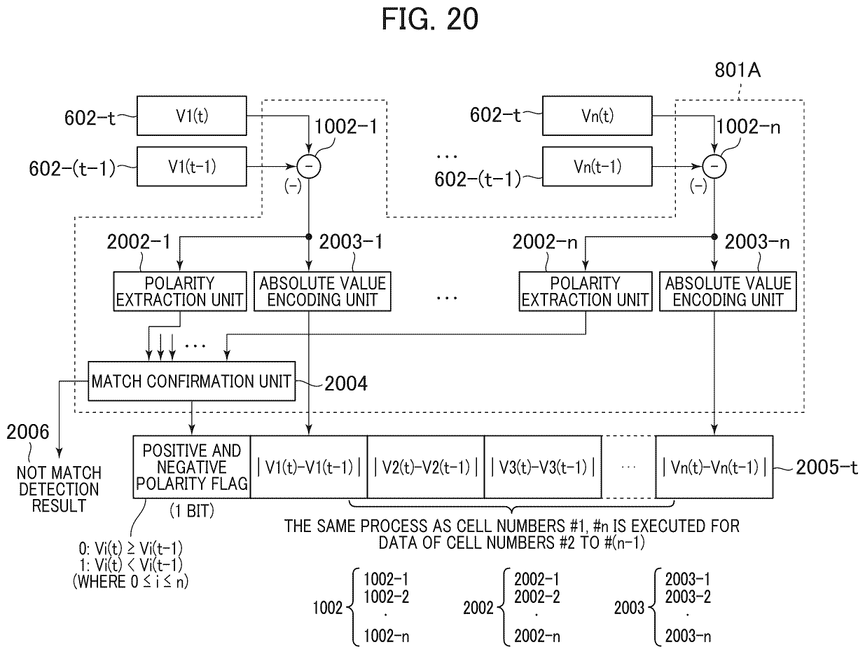

FIG. 20 is a configuration diagram of a first interframe encoding unit 801A according to the third modification example. The first interframe encoding unit 801A includes a plurality of subtractors 1002-1 to 1002-n, polarity extraction units 2002-1 to 2002-n, absolute value encoding units 2003-1 to 2003-n, and a match confirmation unit 2004. The match confirmation unit 2004 judges whether or not the positive and negative polarities of all the data, that is, “V1(t)−v1(t−1)” to “Vn(t)−Vn(t−1)” match. The match confirmation unit 2004 outputs data 2005-t after conversion when all the positive and negative polarities match.

The data 2005-t after conversion corresponds to the data illustrated in FIG. 19(b). The match confirmation unit 2004 outputs a not match detection result (2006) when there is even a single not match data, and instructs the mode selection unit 808 not to select this mode. Hereinafter, the polarity extraction units 2002-1 to 2002-n and the match confirmation unit 2004 will be referred to as a “flag generation unit” together. The flag generation unit generates flag information representing the positive and negative value of the difference between the past battery data and the present battery data. The absolute value encoding units 2003-1 to 2003-n encode the absolute values of the differences between “the data of the past frame” and “the data of the present frame” of the respective cells. The detail of the encoding process is the same as the embodiment.

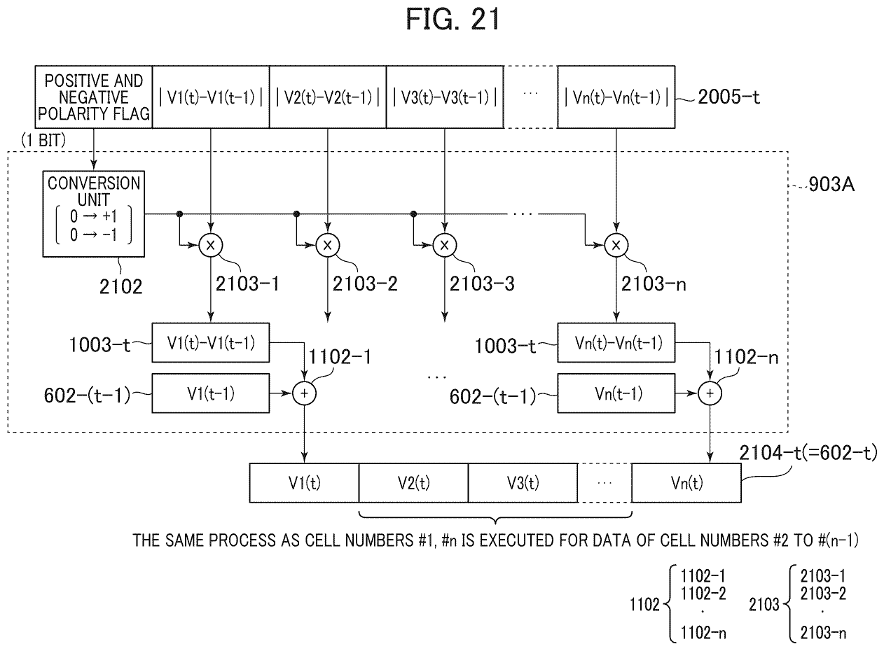

FIG. 21 is a configuration diagram of an interframe decoding unit 903A according to the third modification example. The interframe decoding unit 903A includes a plurality of multipliers 2103-1 to 2103-n, and a conversion unit 2102.

The conversion unit 2102 outputs “+1” when the value of the positive and negative polarity flag included in encoded data (1805-t) is “0”, that is, in the case of a flag representing a positive value, and outputs “−1” when the value of the positive and negative polarity flag is “1” and in the case of a flag representing a negative value. Next, by using the multipliers 2103-1 to 2103-n, the product of the “+1” or “−1” corresponding to the flag and the absolute value included in the encoded data (2005-t) is calculated. Then, after the returning to the frame difference data “V1(t)−V1(t−1)” to “Vn(t)−Vn(t−1)” (1003-t) before the taking of the absolute values is performed, the addition of the frame difference data “V1 (t)−V1(t−1)” to “Vn(t)−Vn(t−1)” (1003-t) with the previously decoded “V1(t−1) to Vn(t−1)” (602-(t−1)) is performed, thereby obtaining data before encoding for this time “V1 (t) to Vn (t)” (2104-t).

According to the third modification example, the following operation and effect are obtained.

(6) The first interframe encoding unit 801A includes the flag generation unit 2002Z that generates flag information representing the positive and negative value of the difference between the past battery data and the present battery data, and the absolute value encoding units 2003-1 to 2003-n that perform encoding by using data representing the absolute values of the differences. Therefore, the data length of the encoded data can be reduced.

### Fourth Modification Example

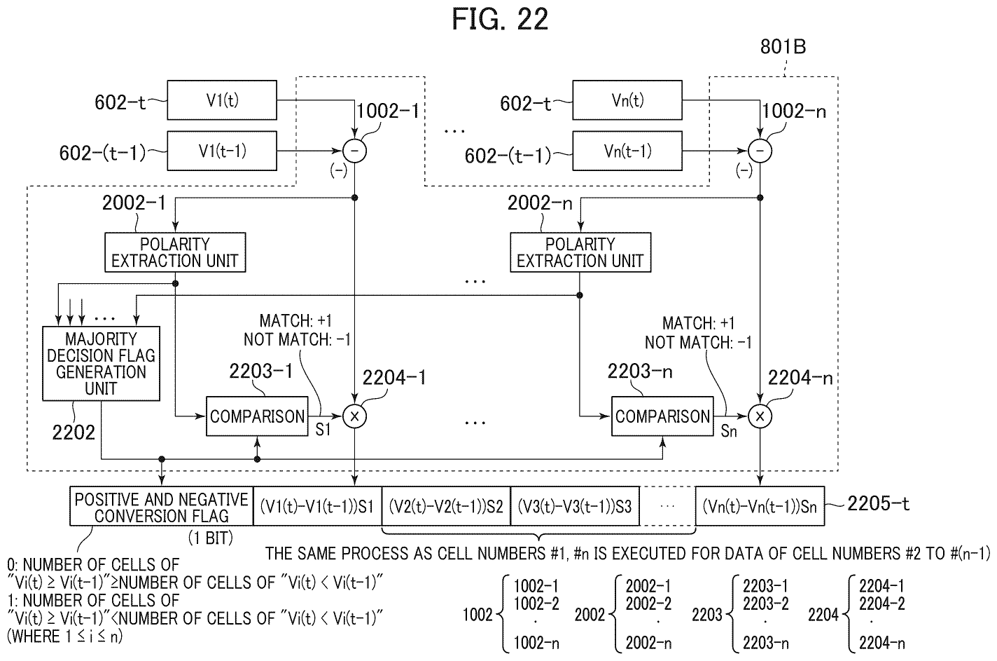

FIG. 22 is a configuration diagram of a second interframe encoding unit 801B according to a fourth modification example. The second interframe encoding unit 801B according to the fourth modification example is different from the third modification example in that an effect is exerted even when the positive and negative polarity flags do not match. Hereinbelow, this will be described in detail.

The second interframe encoding unit 801B includes a majority decision flag generation unit 2202, comparators 2203-1 to 2203-n, integrators 2204-1 to 2204-n, and the subtractors 1002-1 to 1002-n. The majority decision flag generation unit 2202 takes the majority decision of the positive and negative polarities of the respective cells, and decides the positive and negative conversion flag. Specifically, in the majority decision flag generation unit 2202, when the number of positive values is larger than the number of negative values, or the number of positive values and the number of negative values are equal, that is, when the number of cells of “Vi(t)≥Vi(t−1)”≥the number of cells of “Vi(t)<Vi(t−1)”, “0” is the positive and negative conversion flag. In addition, in the majority decision flag generation unit 2202, when the number of negative values is larger than the number of positive values, that is, when the number of cells of “Vi(t)≥Vi(t−1)”<the number of cells of “Vi(t)<Vi(t−1)”, “1” is the positive and negative conversion flag.

Further, the second interframe encoding unit 801B uses the comparators 2203-1 to 2203-n to compare the positive and negative polarity of the respective cells and the positive and negative conversion flag, and outputs “+1” when both match, and outputs “−1” as comparison results (S1 to Sn) when both do not match. Then, the integrators 2204-1 to 2204-n multiply the outputs and the outputs of the respective subtractors 1002-1 to 1002-n. The second interframe encoding unit 801B outputs, as encoded data (2205-t), the thus obtained frame differences ((V1(t)−V1(t−1))S1) to (Vn(t)−Vn(t−1))Sn)) after the positive and negative conversion together with the positive and negative conversion flag. Note that since the calculation results from the integrators 2204-1 to 2204-n are information in which the positive and negative conversion flag of the encoded data (2205-t) is excluded, the comparators 2203-1 to 2203-n and the integrators 2204-1 to 2204-n can also be referred to as a “second absolute value encoding unit”.

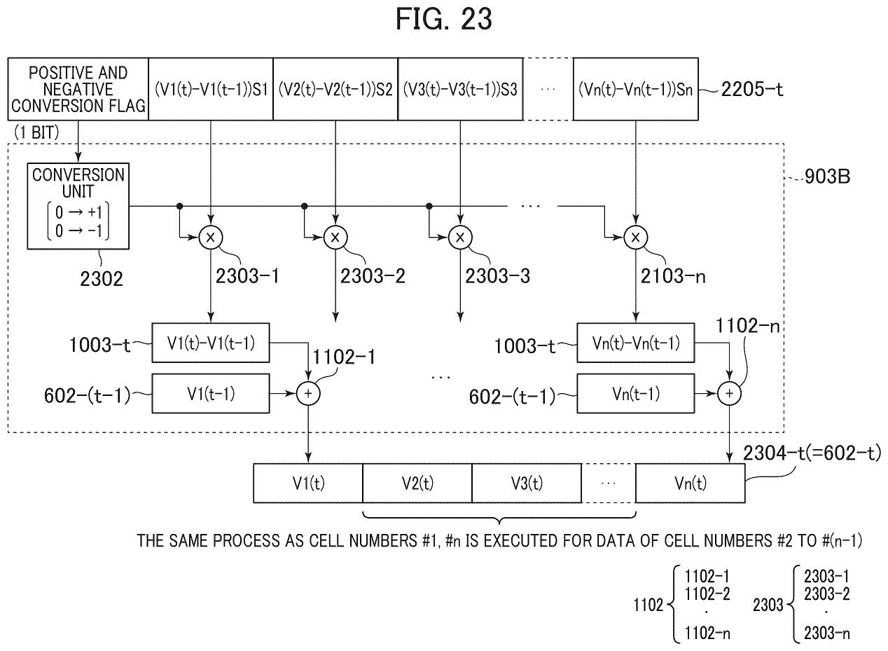

FIG. 23 is a configuration diagram of an interframe decoding unit 903B according to the fourth modification example. Although the information stored as the encoded data (2205-t) is different from the third modification example, the configuration and process of the interframe decoding unit 903B are the same as the configuration and process of the interframe decoding unit 903A illustrated in FIG. 21.

According to the fourth modification example, the following operation and effect are obtained.

(7) The first encoding unit, that is, the interframe encoding unit 801 includes the majority decision flag generation unit 2202 that generates flag information representing the majority decision result of the number of positive values and the number of negative values of the differences between the past battery data and the present battery data, and the second absolute value encoding units that perform encoding by using the battery data converted on the basis of the majority decision results, that is, the comparators 2203-1 to 2203-n and the integrators 2204-1 to 2204-n. Therefore, the data length of the encoded data can be reduced in various cases. Specifically, this is as follows. That is, although it is assumed that in the third modification example, the positive and negative polarity flags match, there is also a case where all the “positive and negative polarity flags” do not match. For example, the deviation of time to measure the voltages of the respective battery cells (sampling time), the forced discharge operation (balancing) of each battery cell for preventing overcharge, the difference in the parasitic capacitance between the respective batteries, and the like become causes, and there is a case where all the positive and negative polarity flags do not match. Even in such a case, in this modification example, the data length of the encoded data can be reduced.

### Fifth Modification Example

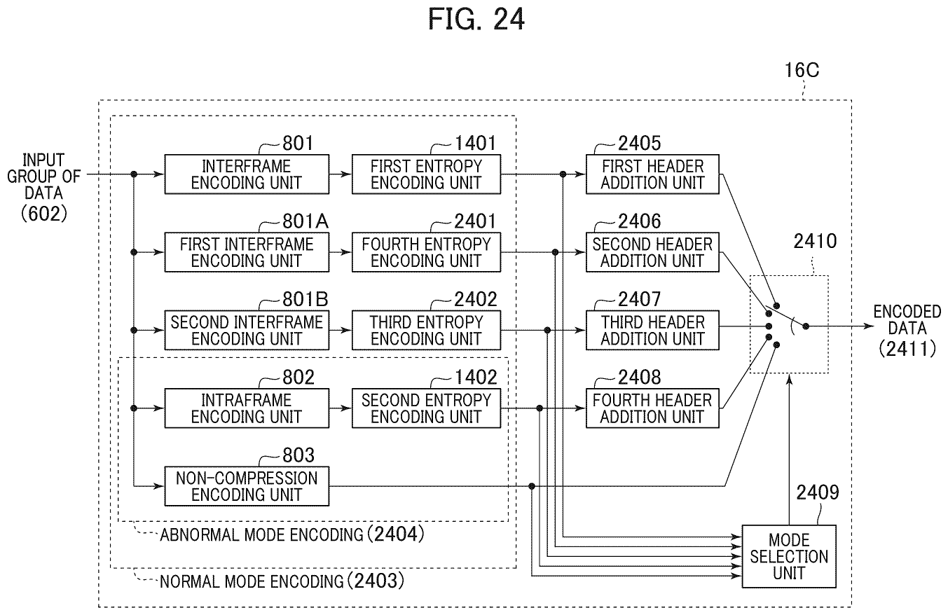

FIG. 24 is a configuration diagram of an encoding unit 16C according to a fifth modification example. The encoding unit 16C includes the interframe encoding unit 801, the first interframe encoding unit 801A, the second interframe encoding unit 801B, the intraframe encoding unit 802, the non-compression encoding unit 803, the first entropy encoding unit 1401, a fourth entropy encoding unit 2401, a third entropy encoding unit 2402, the second entropy encoding unit 1402, a first header addition unit 2405, a second header addition unit 2406, a third header addition unit 2407, a fourth header addition unit 2408, a mode selection unit 2409, and a selection unit 2410.

The operations of the interframe encoding unit 801, the intraframe encoding unit 802, the non-compression encoding unit 803, the first entropy encoding unit 1401, and the second entropy encoding unit 1402 are as described in the first modification example. The operation of the first interframe encoding unit 801A is as described in the third modification example. The operation of the second interframe encoding unit 801B is as described in the fourth modification example.

The fourth entropy encoding unit 2401 subjects the output of the first interframe encoding unit 801A to the entropy encoding process. The third entropy encoding unit 2402 subjects the output of the second interframe encoding unit 801B to the entropy encoding process. The first header addition unit 2405 to the fourth header addition unit 2408 add headers corresponding to the outputs of the respective encoding units. The mode selection unit 2409 selects, among the five encoded data, the encoded data having the shortest data length, and causes the selection unit 2410 to select the encoded data.

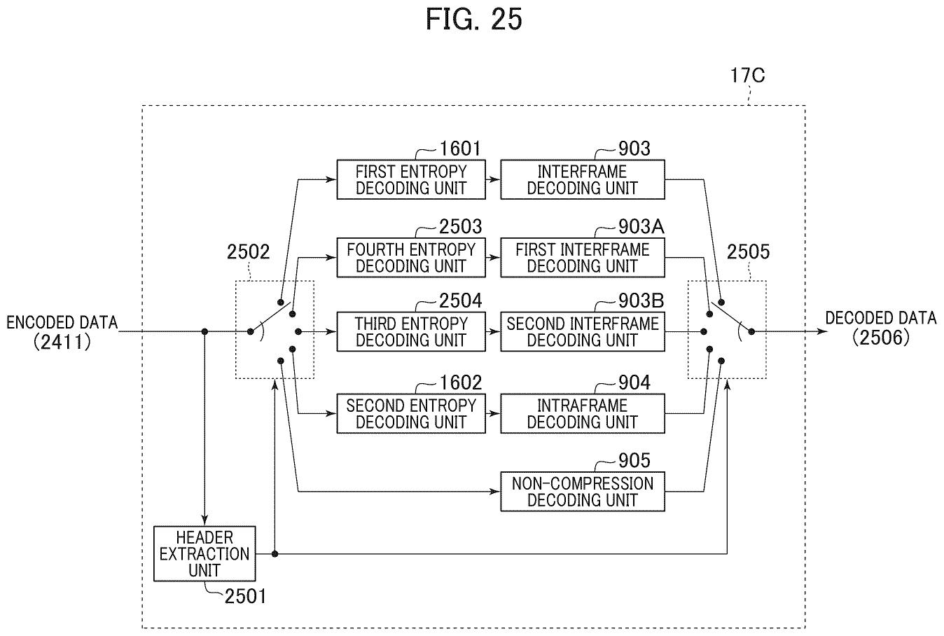

FIG. 25 is a configuration diagram of a decoding unit 17C according to the fifth modification example. The decoding unit 17C includes the interframe decoding unit 903, the first interframe decoding unit 903A, the second interframe decoding unit 903B, the intraframe decoding unit 904, the non-compression decoding unit 905, the first entropy decoding unit 1601, a fourth entropy decoding unit 2503, a third entropy decoding unit 2504, the second entropy decoding unit 1602, a header extraction unit 2501, a decoding mode selection unit 2502, and an output selection unit 2505.

The header extraction unit 2501 extracts the header of encoded data 2411, decides, from the contents of the header, which of the decoding units is selected, and instructs the selected decoding unit to the decoding mode selection unit 902 and the output selection unit 906. The decoding mode selection unit 902 outputs the encoded data 810 to the entropy decoding unit connected to the decoding unit instructed from the header extraction unit 901.

The operations of the interframe decoding unit 903, the intraframe decoding unit 904, the non-compression decoding unit 905, the first entropy decoding unit 1601, and the second entropy decoding unit 1602 are as described in the first modification example. The operation of the first interframe decoding unit 903A is as described in the third modification example. The operation of the second interframe decoding unit 903B is as described in the fourth modification example. The fourth entropy decoding unit 2503 subjects the inputted encoded data 2411 to the entropy decoding process, and outputs the entropy decoded data to the first interframe decoding unit 903A. The third entropy decoding unit 2504 subjects the inputted encoded data 2411 to the entropy decoding process, and outputs the entropy decoded data to the second interframe decoding unit 903B.

### Sixth Modification Example

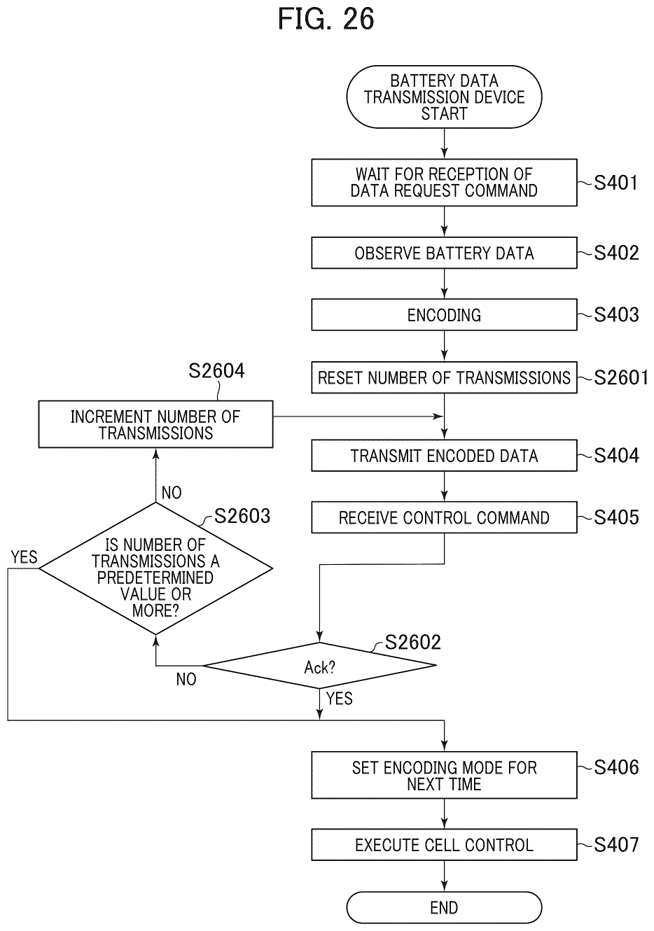

FIG. 26 is a flowchart illustrating the operation of the battery data transmission device B according to a sixth modification example. In this modification example, the battery data transmission device B further includes a retransmission unit R. In FIG. 26, the steps S2601 to S2604 that are processes for retransmitting data are added to the flowchart illustrating the operation of the battery data transmission device B illustrated in FIG. 4 according to the embodiment. Hereinbelow, the processes of the added steps S2601 to S2604 will be mainly described. The processes of the steps S2601 to S2604 are executed by the retransmission unit R. Note that like the transmission control unit 15 and the encoding unit 16, for example, the retransmission unit R is achieved in such a manner that the CPU develops the program stored in the ROM into the RAM, and executes the program.

In the step S2601 executed following the step S403, the retransmission unit R resets the number of retransmissions to zero, and proceeds to the step S404. When the step S404 and the step S405 are executed, the retransmission unit R executes the step S2602. In the step S2602, the retransmission unit R judges whether or not the normal response (Ack) is included in the control command received in the step S405. When judging that the normal response is included, the retransmission unit R proceeds to the step S406, and when judging that the normal response is not included, the retransmission unit R proceeds to the step S2603.

In the step S2603, the retransmission unit R judges whether or not the number of retransmissions is a predetermined value or more. When judging that the number of retransmissions is a predetermined value or more, the retransmission unit R proceeds to the step S406 without performing retransmission, and when judging that the number of retransmissions is less than a predetermined value, the retransmission unit R proceeds to the step S2604. In the step S2604, the retransmission unit R increments the number of transmissions, that is, increases the number of transmissions by “1”, and returns to the step S404.

According to this modification example, the following operation and effect are obtained.

(8) The battery data transmission device B further includes the retransmission unit R that retransmits the previously transmitted encoded data when the previous transmission data communication is abnormal. Therefore, even if an abrupt data error occurs, while the same encoded data is retransmitted several times, the possibility that can achieve transmission without a data error can be increased. Then, since the battery data transmission device B enters the abnormal mode only in the case where a data error occurs even when retransmission is performed, encoding in the normal mode that can compress data into a smaller data amount can be often used.

### Seventh Modification Example

In the above-described embodiment, after the respective encoding units actually perform encoding, the mode selection unit 808 selects, in principle, data having the shortest data length, and selects, in the abnormal state, data having the shortest data length except for the output of the interframe encoding unit 801. However, the optimal encoding method may be previously selected according to the operation mode of the vehicle. For example, the absolute value of the acceleration of the vehicle is made to be an evaluation index, and when this value is a predetermined threshold value or less, that is, the speed change is small, the interframe encoding unit 801 is operated, so that this output is encoded data. In addition, when this value is larger than the predetermined threshold value, that is, the speed change is large, the intraframe encoding unit 802 is operated, so that this output is encoded data. However, in the abnormal state of communication, the interframe encoding unit 801 is not adopted, which is the same as the embodiment.

### Eighth Modification Example

In the above-described embodiment, the encoding unit 16 should include at least one of the intraframe encoding unit 802 and the non-compression encoding unit 803. In this case, the decoding unit 17 should include, of the intraframe decoding unit 904 and the non-compression decoding unit 905, one of the decoding units corresponding to the configuration included in the encoding unit 16.

In the above-described respective embodiments and modification examples, the configurations of the functional blocks are only an example. Some functional configurations represented as the separated functional blocks may be integrally configured, and the configuration represented in one functional block diagram may be divided into two or more functions. In addition, a portion of the function that each functional block has may be included in other functional blocks.

The above-described respective embodiments and modification examples may be respectively combined. In the above, various embodiments and modification examples have been described, but the present invention is not limited to these contents. Other forms considered within the scope of the technical idea of the present invention are also included within the scope of the present invention.

### REFERENCE SIGNS LIST

15 . . . Transmission control unit
16 . . . Encoding unit
17 . . . Decoding unit
18 . . . Abnormality detection unit
801 . . . Interframe encoding unit
802 . . . Intraframe encoding unit
803 . . . Non-compression encoding unit
808 . . . Mode selection unit
B . . . Battery data transmission device
M . . . Battery management device

1. A battery data transmission device that detects the states of a plurality of battery cells, and transmits, via a transmission path, battery data that is data regarding the detected plurality of battery cells, the device comprising:
an encoding unit that has a plurality of encoding modes and encodes the battery data into encoded data;
a mode selection unit that selects any one encoding mode from the plurality of encoding modes; and
a transmission control unit that transmits, to a battery management device, the encoded data in the encoding mode selected by the mode selection unit, and receives, from the battery management device, reception information on the transmitted data,
wherein the mode selection unit selects, when the previous transmission data communication is abnormal according to the reception information from the battery management device, as the encoding mode for the transmission for this time, the encoding mode in which the past battery data is not used in decoding.

2. The battery data transmission device according to claim 1,
wherein the encoding unit includes:
a first encoding unit that performs encoding by using the past battery data; and
a second encoding unit that performs encoding without using the past battery data.

3. The battery data transmission device according to claim 1,
wherein when the previous transmission data communication is not abnormal, the mode selection unit selects the encoding mode that has generated the encoded data having the shortest code length, among a plurality of encoded data calculated by the encoding unit.

4. The battery data transmission device according to claim 2,
wherein the first encoding unit includes:
a flag generation unit that generates flag information representing the positive and negative value of the difference between the past battery data and the present battery data; and
an absolute value encoding unit that performs encoding by using data representing the absolute value of the difference.

5. The battery data transmission device according to claim 2,
wherein the first encoding unit includes:
a flag generation unit that generates flag information representing the majority decision result of the number of positive values and the number of negative values of the difference between the past battery data and the present battery data; and
a second absolute value encoding unit that performs encoding by using the battery data converted on the basis of the majority decision result.

6. The battery data transmission device according to claim 1,
further comprising a retransmission unit that retransmits the previously transmitted encoded data when the previous transmission data communication is abnormal.

7. A battery management device comprising:
a transmission control unit that communicates with a battery data transmission device that wirelessly transmits encoded data obtained by encoding battery data;
a decoding unit that decodes the encoded data to obtain the battery data;
an abnormality detection unit that detects the abnormality of the encoded data received by the transmission control unit or an abnormality when the encoded data is decoded by the decoding unit; and
an instruction unit that outputs, to the battery data transmission device, as an encoding mode for the transmission for the next time, an instruction for selecting the encoding mode in which the past battery data is not used in decoding when the abnormality detection unit detects the abnormality.

8. A battery data transmission method for detecting the states of a plurality of battery cells and transmitting, via a transmission path, battery data that is data regarding the detected plurality of battery cells, the method comprising:
a data encoding process for encoding the battery data by using any one of a plurality of encoding modes;
an encoding mode selection process for selecting any one encoding mode from the plurality of encoding modes; and
a data transmission and reception process for transmitting, to a battery management device, encoded data in the encoding mode selected by the encoding mode selection process, and receiving, from the battery management device, reception information on the transmitted data,
wherein the encoding mode selection process selects, when the previous transmission data communication is abnormal according to the reception information from the battery management device, as the encoding mode for the transmission for this time, the encoding mode in which the past battery data is not used in decoding.

9. A battery data transmission system that includes a battery data transmission device that transmits, via a transmission path, encoded data obtained by encoding battery data that is data regarding a battery, and a battery management device that receives the encoded data,
the battery data transmission system further including an abnormality detection unit that detects the abnormality of the encoded data,
wherein the battery data transmission device includes: an encoding unit that generates the encoded data by using the battery data; and
a transmission control unit that transmits, via the transmission path, the encoded data to the battery management device,
the encoding unit has, as operation modes, at least a first mode and a second mode,
the first mode is a mode that generates the encoded data by using the past battery data;
the second mode is a mode that generates the encoded data without using the past battery data, and
when detecting an abnormality in the encoded data, the abnormality detection unit causes the encoding unit to apply the second mode in encoding for the next time.
